(19) United States
(12) Patent Application Publication
(10) Pub. No.: US 2009/0301656 A1
(43) Pub. Date: Dec. 10, 2009

(54) MICROWAVE PLASMA PROCESSING APPARATUS

(75) Inventors: Shinya NISHIMOTO, Amagasaki City (JP); Kazunari SAKATA, Sendai City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/478,197

(22) Filed: Jun. 4, 2009

(30) Foreign Application Priority Data
Jun. 6, 2008 (JP) 2008-149401

(51) Int. Cl. H01L 21/465; C23C 16/511

(52) U.S. Cl. 156/345.41; 118/723 AN; 257/E21.485

(57) ABSTRACT

An end of the slot plate of the microwave antenna, which constitutes a microwave plasma processing apparatus, is held and fixed by being held between a pair of metal bodies.

### CROSS-REFERENCE TO RELATED PATENT APPLICATIONS

This application claims the benefit of Japanese Patent Application No. 2008-149401, filed on Jun. 6, 2008, in the Japan Patent Office, the disclosure of which is incorporated herein in its entirety by reference.

### BACKGROUND OF THE INVENTION

1. Field of the Invention

The present invention relates to a microwave plasma processing apparatus that can be highly appropriate for the fabrication of ultra-fine semiconductor devices or the fabrication of high-resolution flat panel display apparatuses that have liquid crystal display devices.

2. Description of the Related Art

A plasma processing process and a plasma processing apparatus are essential technologies for the fabrication of an ultra-fine semiconductor device, which has gate lengths close to or smaller than 0.1 μm and is often referred as a deep submicron device or a deep sub-quarter micron device, or the fabrication of a high-resolution flat panel display apparatus that has a liquid crystal display device.

Plasma processing apparatuses used in the fabrication of semiconductor devices or liquid crystal displays employ various conventional plasma excitation methods. Among them, a parallel plate type high frequency excitation plasma processing apparatus or an inductively coupled type plasma processing apparatus is generally used.

However, these conventional plasma processing apparatuses have problems such as non-uniform plasma formation and difficulty of performing a plasma process uniformly over an entire substrate to be processed at a high processing speed, that is, large throughput due to limited regions with high electron densities. The problems become more significant especially when a substrate having a large diameter is processed. Furthermore, such conventional plasma processing apparatuses have essential problems such as damages inflicted to semiconductor devices formed on a substrate to be processed due to high electron temperature, severe metal contamination due to sputtering on sidewalls of a processing chamber, etc. Therefore, it becomes more and more difficult for a conventional plasma processing apparatus to fulfill strict demands for finer semiconductor devices, finer liquid crystal displays, and improved productivity of the same.

Considering the problems as stated above, a microwave plasma processing apparatus, which uses high-density plasma excited by a microwave field instead of a direct current magnetic field, has been suggested. For example, a plasma processing apparatus, in which a planar antenna (radial line slot antenna) having a plurality of slots that are disposed to generate uniform microwaves emits microwaves into a processing container and plasma is excited by ionizing gas within a vacuum container using the microwave field, has been suggested (e.g. refer to Japanese Patent Laid-Open Publication No. Hei 9-63793).

Microwave plasma excited as described above can have high plasma density throughout a large area beneath an antenna and enables a uniform plasma process in a short period of time. Furthermore, since microwave plasma formed as described above is excited by microwaves, the electron temperature is low, and damages to a substrate to be processed or metal contamination can be avoided. Furthermore, since uniform plasma can be easily excited on a large substrate, microwave plasma processing can be easily applied to the fabrication of semiconductor devices using semiconductor substrates having large diameters or the fabrication of large liquid crystal display devices.

[Patent 1] Japanese Patent Laid-Open Publication No. Hei 9-63793

FIG. 1 is a sectional view schematically showing an example of the configuration of a conventional microwave plasma processing apparatus 10, and FIG. 2 is a detailed sectional view showing that an end 133A of a slot plate 133 and a top plate 135 of a microwave antenna 13 of the conventional microwave plasma processing apparatus 10 shown in FIG. 1 are fixed. Furthermore, the shape of a microwave plasma processing apparatus, particularly, a microwave antenna thereof is circular when viewed from above. Although not shown, the shape of each of the components of the microwave plasma processing apparatus is also circular when viewed from above.

The conventional microwave plasma processing apparatus 10 shown in FIG. 1 includes a processing container 11 that has a holder 111 holding a substrate S to be processed, a gas shower 12 that is disposed within the processing container 11, and a gas introduction pipe 17. The gas introduction pipe 17 is formed to penetrate an inner wall 11B of the processing container 11, is supported by the inner wall 11B, and supplies inert gas mainly for plasma generation into the processing container 11. The gas shower 12 is fixed on the inner wall 11B of the processing container 11 by a jig (not shown), and is configured to supply gas for a plasma process into the processing container 11 via openings 12A from a gas source (not shown). Furthermore, an opening 11A is formed in a lower portion of the processing container 11 for connecting to, for example, an exhaust system (not shown) such as a vacuum pump.

Furthermore, the microwave antenna 13 is formed on the processing container 11 to vacuum-seal the processing container 11. A coaxial waveguide 14, extending vertically upward, is formed approximately at the center of the microwave antenna 13, and a coaxial converter 15 is formed at an end of the coaxial waveguide 14, the end being opposite to another end of the coaxial waveguide 14 facing the microwave antenna 13.

The coaxial waveguide 14 includes an inner conductor 141 and an outer conductor 142. A top end 141A of the inner conductor 141 and a top surface of the coaxial converter 15 are fixed by a screw 21, whereas a top end 142A of the outer conductor 142 and a bottom surface of the coaxial converter 15 are fixed by a screw 22. Thus, the coaxial waveguide 14 and the coaxial converter 15 are mechanically and electrically connected.

The microwave antenna 13 includes a cooling jacket 131, a wavelength-shortening plate 132 formed to face the cooling jacket 131, and the slot plate 133 formed on a primary surface of the wavelength-shortening plate 132, the primary surface being opposite to another primary surface of the wavelength-shortening plate 132 on which the cooling jacket 131 is formed. Furthermore, a plurality of slots (not shown) that emit microwaves are formed on the slot plate 133.

Furthermore, the cooling jacket 131, the wavelength-shortening plate 132, and the slot plate 133 are formed on the top plate 135 of the microwave antenna 13. The top plate 135 is held by a top end of the inner wall 11B of the processing container 11.

A bottom end 142B of the outer conductor 142 of the coaxial waveguide 14 and the cooling jacket 131 of the microwave antenna 13 are fixed by a screw 23. Thus, the coaxial waveguide 14 and the microwave antenna 13 are mechanically and electrically connected.

Furthermore, the cooling jacket 131 is provided mainly to prevent the microwave antenna 13 from being heated by radiant heat of plasma generated in the processing container 11, and is configured so that coolant flows through communication holes 131A formed in the cooling jacket 131. Furthermore, a cover 134 is attached to the top surface of the cooling jacket 131 via an O-ring 28 by a screw 24, and the communication hole 131 is blocked by the cover 134.

Furthermore, as shown in FIGS. 1 and 2, the end 133A of the slot plate 133 is fixed to the cooling jacket 131 by a screw 26.

However, when plasma is generated in the processing container 11 and a process on the substrate S set on the holder 111 begins, the microwave antenna 13 is heated so that the temperature of the microwave antenna 13 exceeds 100° C., even if the microwave antenna 13 is entirely cooled by the cooling jacket 131. Therefore, even if the slot plate 133 is fixed to the cooling jacket 131 by the screw 26, positions of the slots formed on the slot plate 133 change.

Meanwhile, microwaves, which are introduced to the microwave antenna 13 via the coaxial converter 15 and the coaxial waveguide 14 from a microwave source (not shown), propagate in the wavelength-shortening plate 132, and then are emitted into the processing container 11 from the slot plate 133 via the top plate 135. Therefore, if a position of a slot changes as described above, the emission state of microwave from the slot changes, then the microwaves cannot be uniformly emitted into the processing container 11, and thus the process on the substrate S cannot be uniformly performed. As a result, the stability or reliability of a microwave plasma processing apparatus is deteriorated.

### SUMMARY OF THE INVENTION

The present invention is purposed to generate uniform plasma by preventing changes in locations of slot plate of a microwave antenna constituting a microwave plasma processing apparatus and preventing variations in desired propagation of microwave.

According to an aspect of the present invention, there is provided a microwave plasma processing apparatus including a processing container including a holder therein for holding a substrate to be processed, an exhaust system connected to the processing container, a gas supplying unit which is connected to the processing container and supplies gas for plasma generation, a microwave antenna provided above the processing container to vacuum-seal the processing container, a coaxial waveguide which extends vertically upward and is provided approximately at the center of the microwave antenna, a coaxial converter which is provided at an end of the coaxial waveguide, the end being opposite to another end of the coaxial waveguide facing the microwave antenna, and a microwave source which is electrically connected to the microwave antenna via the coaxial waveguide and the coaxial converter and supplies predetermined microwaves to the microwave antenna, wherein the microwave antenna includes a cooling jacket, a wavelength-shortening plate facing the cooling jacket, and a slot plate provided on a primary surface of the wavelength-shortening plate, the primary surface being opposite to another primary surface of the wavelength-shortening plate on which the cooling jacket is provided, and an end of the slot plate is fixed and held by being held between metal bodies.

According to the present invention, the slot plate constituting the microwave antenna may be held and fixed by being held between metal bodies, instead of conventional attachment and fixation of the slot plate to the cooling jacket using a screw. Thus, unlike in related arts, the slot plate can freely expand and contract in an in-plane direction of the slot plate. Thus, the slot place can expand and contract in its radial direction.

Therefore, even when plasma is generated in the processing container, a process on the substrate S set on the holder begins, and thus the microwave antenna is heated, the thermal expansion of the slot plate may occur in the radial direction of the slot plate. Therefore, the slot plate widens the gap between the wavelength-shortening plate and the top plate by pushing itself into the gap, and thus the slot plate can expand in its radial direction while maintaining planarity without become deformed in the vertical direction. Thus, a path for propagation of the microwave will not be changed. As a result, uniform microwave can be emitted, and thus uniform plasma can be generated.

Furthermore, since the slot plate stays flat even in thermal expansion, the wavelength-shortening plate and the top plate may maintain status of close contact, with the slot plate interposing between them. Therefore, deterioration of cooling efficiency by the cooling jacket especially with respect to the top plate may be avoided.

Furthermore, the metal bodies may be a pair of metal bodies, and the end of the slot plate may be fixed and held by being held between the pair of metal bodies above and below the slot plate, respectively. In this case, expansion and contraction of the slot plate in its radial direction can be improved, and thus the effect described above may be obtained more effectively.

Furthermore, the metal body may be a helical-shaped metal body formed by winding a metal wire around an axis approximately parallel to the primary surface of the slot plate. Alternatively, the metal body may be a helical-shaped metal body formed by winding a metal strip around an axis approximately parallel to the primary surface of the slot plate.

Since such metal body has high elasticity, the slot plate can be fixed and supported more effectively while the expansion and contraction of the slot plate due to thermal expansion in its radial direction are secured.

Meanwhile, microwaves supplied by the microwave source propagate in the wavelength-shortening plate and are emitted into the processing container via the top plate from slots of the slot plate. Furthermore, electric current due to the microwaves propagates in the surface of the metal bodies, and the surface of the cooling jacket facing the wavelength-shortening plate. At this point, if electrical contact between the slot plate and the metal bodies is not close enough, the microwave current cannot propagate smoothly, and thus propagation of the microwaves may not be favorably maintained.

However, in the present embodiment, a sufficient contact area between the metal body and the slot plate can be secured, and thus a sufficient electrical contact area between the slot plate and the metal body can be secured. Thus, there are no disadvantages regarding the propagation of microwaves due to insufficient electrical contact.

The metal body may be a metal leaf spring. Even in this case, since such metal body has high elasticity, the slot plate can be fixed and supported more effectively while the expansion and contraction of the slot plate due to thermal expansion in its radial direction are secured. Furthermore, a sufficient electrical contact area between the slot plate and the metal body can be secured by controlling the shape, the size, and like of the metal leaf spring, and thus there are no disadvantages regarding the propagation of microwaves due to insufficient electrical contact.

The metal body may include a first metal member, which has elasticity, and a second metal member, which is formed on the surface of the first metal member and has good electrical conductivity. In this case, due to the elasticity of the first metal member, the slot plate can be fixed and supported more effectively while the expansion and contraction of the slot plate due to thermal expansion in its radial direction are secured, and the electrical contact between the slot plate and the metal body can be favorably performed due to the good electrical conductivity of the second metal body. Therefore, a propagation of microwave current can be uniformly maintained, and thus overall propagation of the microwaves can be maintained favorably.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view schematically showing an example of the configuration of a conventional microwave plasma processing apparatus;

FIG. 2 is a detailed sectional view showing that an end of a slot plate and a top plate of a microwave antenna of the conventional microwave plasma processing apparatus shown in FIG. 1 are fixed;

FIG. 3 is a sectional view of an example of the configuration of a microwave plasma processing apparatus according to an embodiment of the present invention;

FIG. 4 is a detailed sectional view showing that an end of a slot plate and a top plate of an microwave antenna of the microwave plasma processing apparatus shown in FIG. 3 are fixed;

FIG. 5 is a diagram showing an example of configuration of a metal body of the microwave plasma processing apparatus shown in FIG. 3;

FIG. 6 is a diagram showing another example of configuration of a metal body of the microwave plasma processing apparatus shown in FIG. 3; and

FIG. 7 is a diagram showing another example of configuration of a metal body of the microwave plasma processing apparatus shown in FIG. 3.

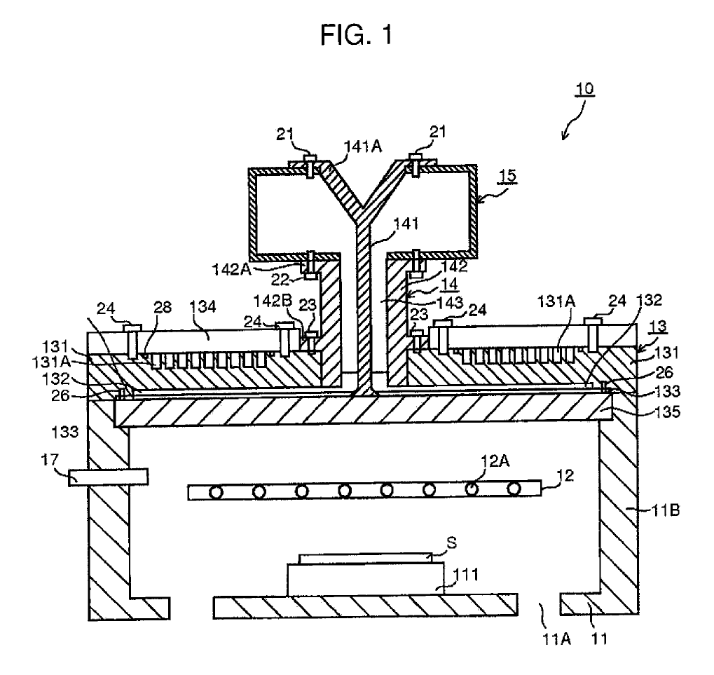

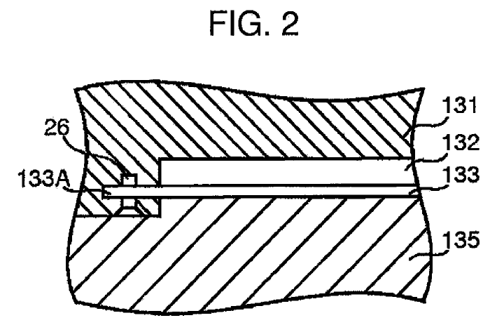

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings.

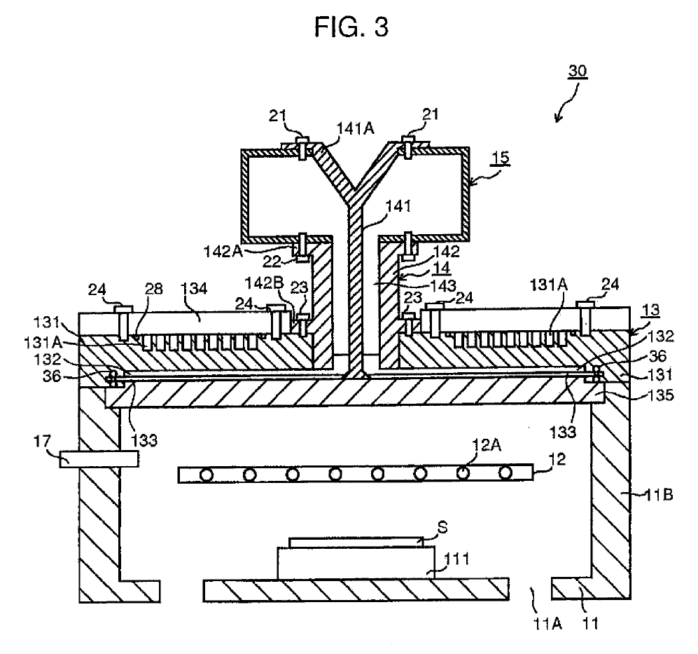

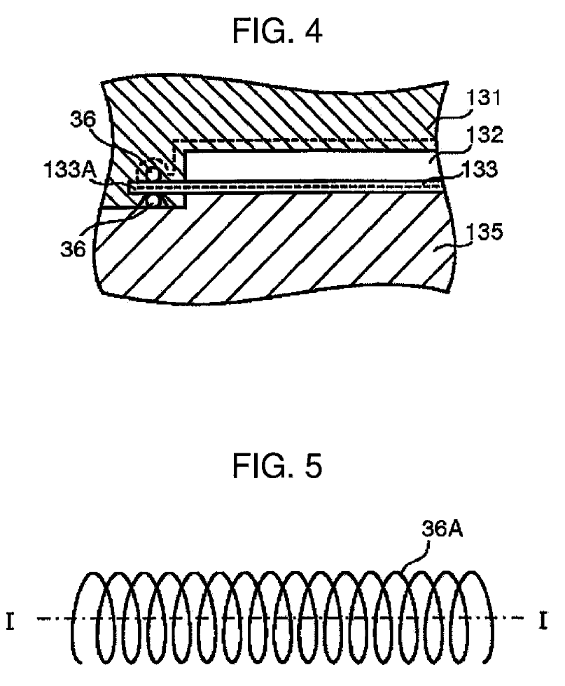

FIG. 3 is a sectional view of an example of the configuration of a microwave plasma processing apparatus 30 according to an embodiment of the present invention, and FIG. 4 is a detailed sectional view showing that an end 133A of a slot plate 133 and a top plate 135 of an microwave antenna 13 of the microwave plasma processing apparatus 30 shown in FIG. 3 are fixed. Furthermore, the shape of a microwave plasma processing apparatus, particularly, a microwave antenna thereof is circular when viewed from above. Although not shown, the shape of each of the components of the microwave plasma processing apparatus is also circular when viewed from above. Like reference numerals in the drawings denote like elements.

The microwave plasma processing apparatus 30 shown in FIG. 3 includes a processing container 11 that has a holder 111 holding a substrate S to be processed, a gas shower 12 that are disposed in the processing container 11, and a gas introduction pipe 17. The holder 111 may be a suscepter of which the main ingredient is alumina or SiC, for example. In this case, the substrate S to be processed is adsorbed and fixed on the primary surface of the suscepter due to the electrostatic force generated by electrodes formed within the suscepter. Furthermore, if required, a heater for heating the substrate S to be processed may be disposed in the suscepter.

The gas introduction pipe 17 is provided to penetrate an inner wall 11B of the processing container 11 and is held by the inner wall 11B of the processing container 11. The gas shower 12 is fixed on the inner wall 11B of the processing container 11 by a jig (not shown), and is configured to supply a predetermined gas into the processing container 11 via a plurality of openings 12A from a gas source (not shown). Furthermore, since the openings 12A are formed in the lengthwise direction of the gas shower 12 to be a predetermined distance apart from each other, the gas can be uniformly supplied to a location close to the substrate S to be processed, and thus microwave plasma processing can be uniformly performed on the substrate S.

Furthermore, an opening 11A is formed in a lower portion of the processing container 11 for connecting to, for example, an exhaust system (not shown) such as a vacuum pump. The degree of vacuum (pressure) in the processing container 11 is maintained at a suitable level by exhaustion via the opening 11A by using the vacuum pump.

Inert gas such as Ar is supplied into the processing container 11 mainly via the gas introduction pipe 17, and gas such as fluoric gas is supplied into the processing container 11 mainly via the gas shower 12.

Furthermore, the microwave antenna 13 is provided above the processing container 11 to vacuum-seal the processing container 11. The microwave antenna 13 includes a cooling jacket 131, which is formed of a material with excellent heat conductivity (e.g. Al), a wavelength-shortening plate 132, which is formed of a dielectric material (e.g. alumina) and faces the cooling jacket 131, and the slot plate 133, which is formed of a good conductor of electricity (e.g. Cu) on the primary surface of the wavelength-shortening plate 132, the primary surface being opposite to another primary surface of the wavelength-shortening plate 132 on which the cooling jacket 131 is provided.

The cooling jacket 131, the wavelength-shortening plate 132, and the slot plate 133 are sequentially provided on the top plate 135 of the microwave antenna 13. The top plate 135 of the microwave antenna 13 is located on and held by the top end of the inner wall 11B of the processing container 11.

Furthermore, the cooling jacket 131 is provided to cool the microwave antenna 13, particularly, the top plate 135 of the microwave antenna 13. In other words, the cooling jacket 131 is provided mainly to prevent the microwave antenna 13 from being heated by radiant heat of plasma generated in the processing container 11, and is configured so that coolant flows through communication holes 131A formed in the cooling jacket 131. Furthermore, a cover 134 is attached to the top surface of the cooling jacket 131 via an O-ring 28 by a screw 24, and the communication holes 131A are blocked by the cover 134.

Furthermore, as shown in FIGS. 3 and 4, the end 133A of the slot plate 133 is held and fixed by being held between a pair of metal bodies 36 above and below the slot plate 133, respectively. Alternatively, a single metal body may be used instead of a pair of metal bodies, by pressing the single metal body onto the slot plate 133 from above such that the slot plate 133 is held between the single metal body and the top plate 135.

Furthermore, a coaxial waveguide 14, which extends vertically upward, is formed approximately at the center of the microwave antenna 13, and a coaxial converter 15 is provided at an end of the coaxial waveguide 14, the end being opposite to another end of the coaxial waveguide 14 facing the microwave antenna 13.

The coaxial waveguide 14 includes an inner conductor 141 and an outer conductor 142. A top end 141A of the inner conductor 141 and a top surface of the coaxial converter 15 are fixed by a screw 21, whereas a top end 142A of the outer conductor 142 and a bottom surface of the coaxial converter 15 are fixed by a screw 22. Thus, the coaxial waveguide 14 and the coaxial converter 15 are mechanically and electrically connected.

Furthermore, the inner conductor 141 may be cooled by forming the inner conductor 141 with an inner cavity and by flowing coolant via the inner cavity.

Furthermore, a bottom end 142B of the outer conductor 142 of the coaxial waveguide 14 and the cooling jacket 131 are fixed by a screw 23. Thus, the coaxial waveguide 14 and the microwave antenna 13 are mechanically and electrically connected.

Microwaves, which are supplied by a microwave source (not shown), are supplied into the coaxial converter 15, and thus microwaves in the transverse electric (TE) mode and microwaves in the transverse magnetic (TM) mode are mixed. The mixed wave is guided along the coaxial waveguide 14 and is supplied to the microwave antenna 13. At this point, the microwaves in the TM mode propagate in a cavity 143 defined by the inner conductor 141 and the outer conductor 142 of the coaxial waveguide 14 and then propagate in the wavelength-shortening plate 132. Then, the microwaves in the TM mode are emitted by slots (not shown) of the slot plate 133 and are supplied into the processing container 11 via the top plate 135.

Then, gas supplied into the processing container 11 from the gas shower 12 is plasmarized, and operations such as processing the substrate S to be processed are performed by using the plasmarized gas.

Furthermore, electric current due to the microwaves propagates in a surface of the slot plate 133 facing the wavelength-shortening plate 132, the surface of the metal bodies 36, and the surface of the wavelength-shortening plate 132 (a surface of the cooling jacket 131 facing the wavelength-shortening plate 132) (refer to dashed lines in FIG. 4).

Accordingly, when the microwaves are supplied into the processing container 11, plasma is generated, and operations such as processing the substrate S to be processed is performed, the microwave antenna 13 is heated due to radiant heat of the plasma. At this point, the microwave antenna 13 is cooled by flowing a coolant through the communication holes 131A in the cooling jacket 131. However, despite of such temperature control, the microwave antenna 13 is heated so that the temperature of the microwave antenna 13 exceeds 100° C.

Particularly, since the slot plate 133 is formed of a good conductor with electricity, such as Cu, as described above, the slot plate 133 is more significantly affected by heat and expands further due to the heat, as compared to the wavelength-shortening plate 132, which is formed above the slot plate 133 and is formed of alumina, etc.

However, according to the present embodiment, the end 133A of the slot plate 133 is held and fixed by being held between the pair of metal bodies 36. Therefore, even in case where the temperature of the microwave antenna 13 is increased and thus thermal expansion of the slot plate 133 is relatively significant, the end 133A of the slot plate 133 can freely expand and contract in the direction of the radius of the slot plate 133. Thus, the thermal expansion occurs in the direction of the radius of the slot plate 133.

As a result, thermal expansion of the slot plate 133 in vertical directions can be prevented, and thus deterioration of the planarity of the slot plate 133 due to the distortion of the slot plate 133 does not occur. In other words, the slot plate 133 can maintain its planarity even when the slot plate 133 is heated by radiant heat from the inside of the processing container 11, and thus variations in microwaves accompanied with variations in position of the slot plate 133 can be prevented. Therefore, the microwaves can be uniformly emitted through the slot plate 133, and plasma can be generated uniformly in the processing container 11.

Furthermore, since the slot plate 133 maintains its planarity even in case of thermal expansion, no gap is formed between the wavelength-shortening plate 132 and the top plate 135, and thus the wavelength-shortening plate 132 and the top plate 135 tightly hold the slot plate 133. Therefore, cooling efficiency by the cooling jacket 131 especially with respect to the top plate 135 is not deteriorated.

Next, the detailed configuration of the metal body 36 is described below. FIG. 5 is a diagram showing an example of configuration of the metal body 36 (not shown), according to an embodiment of the present invention. In the present embodiment, the metal body 36 is a helical-shaped metal body formed by winding a metal wire 36A around an axis I-I, which is approximately parallel to a primary surface of the slot plate 133. Since such metal body has high elasticity, the slot plate 133 can be fixed and supported more effectively while the expansion and contraction of the slot plate 133 due to thermal expansion in its radial direction are secured.

Furthermore, a sufficient contact area between the metal body 36 and the slot plate 133 can be uniformly secured, and thus a sufficient electrical contact area between the slot plate 133 and the metal body 36 can be secured. Therefore, a path for electric current due to the microwaves to propagate therein as indicated by a dashed line in FIG. 4 can be secured, and thus propagation of the microwaves can be favorably maintained.

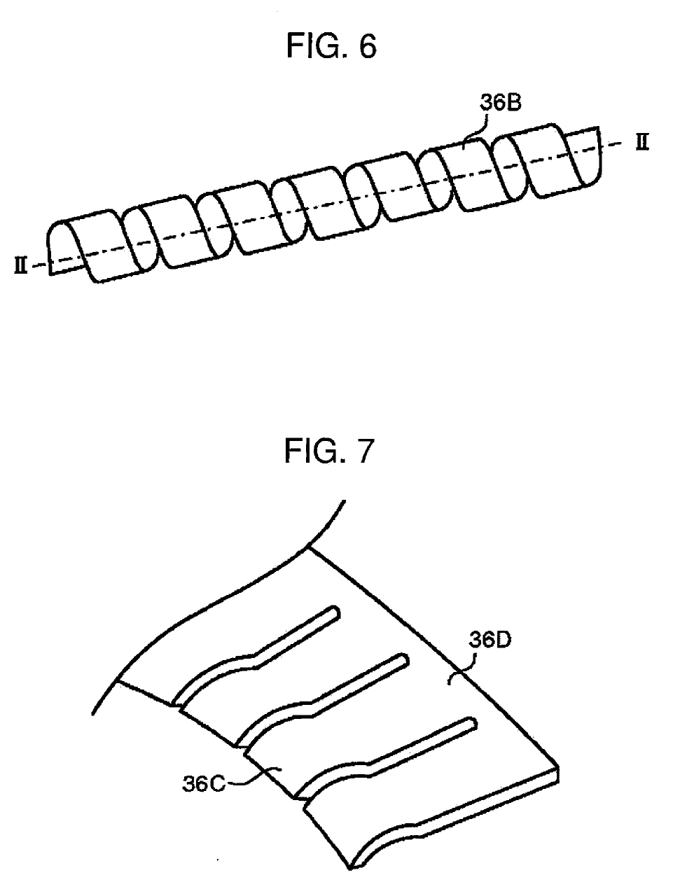

FIG. 6 is a diagram showing another example of the configuration of the metal body 36, according to another embodiment of the present invention. In the present embodiment, the metal body 36 is a helical-shaped metal body formed by winding a metal strip 36B around an axis II-II, which is approximately parallel to the primary surface of the slot plate 133. Similar to the embodiment of FIG. 5, since the metal body 36 has high elasticity, the slot plate 133 can be fixed and supported more effectively while the expansion and contraction of the slot plate 133 due to thermal expansion in its radial direction are secured.

Furthermore, although the embodiments shown in FIGS. 5 and 6 show a single metal body, a plurality of metal bodies may be disposed in a circular shape along the outer perimeter of the slot plate 133.

FIG. 7 is a diagram showing another example of the configuration of the metal body 36, according to another embodiment of the present invention. In the present embodiment, the metal body 36 is an array of a plurality of metal leaf springs 36C. Even in this embodiment, since the metal body 36 has high elasticity, the slot plate 133 can be fixed and held more effectively while the expansion and contraction of the slot plate 133 due to thermal expansion in its radial direction are secured. Furthermore, a sufficient electrical contact area between the slot plate 133 and the metal body 36 can be secured by controlling the shape, the size, and like of the metal leaf spring 36C, and thus there are no disadvantages regarding the propagation of microwaves due to insufficient electrical contact.

Furthermore, FIG. 7 partially shows that the metal leaf springs 36C are connected to a circular supporting member 36D and are arranged in a circular shape along the outer perimeter of the slot plate 133.

Furthermore, although not shown, the metal body 36 may include a first metal member, which has elasticity, and a second metal member, which is formed on the surface of the first metal member and has good electrical conductivity. In this case, due to the elasticity of the first metal member, the slot plate 133 can be fixed and supported more effectively while the expansion and contraction of the slot plate 133 due to thermal expansion in its radial direction are secured, and the electrical contact between the slot plate 133 and the metal body 36 can be favorably performed due to the good electrical conductivity of the second metal body. Therefore, a path for microwave current to propagate can be secured, and thus overall propagation of the microwaves can be maintained favorably.

While the present invention has been particularly shown and described with reference to exemplary embodiments thereof, it will be understood by those of ordinary skill in the art that various changes in form and details may be made therein without departing from the spirit and scope of the present invention as defined by the following claims.

For example, although an end of a slot plate is fixed and supported by being held between a pair of metal bodies above and below the slot plate, respectively, as shown in the above embodiment of FIG. 4, the end of the slot plate may be fixed and held by only one metal body. More particularly, the slot plate may be held by a metal body provided either above or below the slot plate, and the slot plate may be fixed by a top plate or a cooling jacket facing the slot plate.

As described above, in the present invention, thermal deformation of a slot plate of a microwave antenna of a microwave plasma processing apparatus in vertical directions and variations in desired propagation of microwaves can be prevented, and thus plasma can be uniformly generated.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A microwave plasma processing apparatus comprising:
a processing container including a holder therein for holding a substrate to be processed;
an exhaust system connected to the processing container;
a gas supplying unit which is connected to the processing container and supplies gas for plasma generation;
a microwave antenna provided above the processing container to vacuum-seal the processing container;
a coaxial waveguide which extends vertically upward and is provided approximately at the center of the microwave antenna;
a coaxial converter which is provided at an end of the coaxial waveguide, the end being opposite to another end of the coaxial waveguide facing the microwave antenna; and
a microwave source which is electrically connected to the microwave antenna via the coaxial waveguide and the coaxial converter and supplies predetermined microwaves to the microwave antenna,
wherein the microwave antenna comprises a cooling jacket, a wavelength-shortening plate facing the cooling jacket, and a slot plate provided on a primary surface of the wavelength-shortening plate, the primary surface being opposite to another primary surface of the wavelength-shortening plate on which the cooling jacket is provided, and
an end of the slot plate is fixed and held by being held between metal bodies.

2. The microwave plasma processing apparatus of claim 1, wherein the metal bodies are a pair of metal bodies, and the end of the slot plate is fixed and held by being held between the pair of metal bodies above and below the slot plate, respectively.

3. The microwave plasma processing apparatus of claim 1, wherein the metal body is a helical-shaped metal body formed by winding a metal wire around an axis which is approximately parallel to the primary surface of the slot plate.

4. The microwave plasma processing apparatus of claim 1, wherein the metal body is a helical-shaped metal body formed by winding a metal strip around an axis which is approximately parallel to the primary surface of the slot plate.

5. The microwave plasma processing apparatus of claim 1, wherein the metal body is a metal leaf spring.

6. The microwave plasma processing apparatus of claim 1, the metal body comprises a first metal member, which has elasticity, and a second metal member, which is formed on the surface of the first metal member and has good electrical conductivity.
